(19) United States
(12) Patent Application Publication
(10) Pub. No.: US 2026/0147948 A1
(43) Pub. Date: May 28, 2026

(54) MODEL GENERATION APPARATUS, MODEL GENERATION METHOD, AND PROGRAM

(71) Applicant: NEC CORPORATION, Minato-ku, Tokyo (JP)

(72) Inventor: Hisaya WAKAYAMA, Tokyo (JP)

(73) Assignee: NEC CORPORATION, Minato-ku, Tokyo (JP)

(21) Appl. No.: 19/120,263

(22) PCT Filed: Oct. 31, 2022
(86) PCT No.: PCT/JP2022/040742

§ 371 Date: Apr. 11, 2025

(51) Int. Cl. G06F 30/13; G06T 13/20; G06T 17/00

(52) U.S. Cl. CPC G06F 30/13; G06T 13/20; G06T 17/00

(57) ABSTRACT

A model generation apparatus of the present disclosure includes: an acquiring means that acquires first design information of a designed object; a first generating means that generates occupancy information representing presence or absence of occupancy of the designed object in each position in a three-dimensional space, according to the first design information; and a second generating means that generates a model shape of the designed object composed of a combination of a plurality of default structures, according to the occupancy information.

### TECHNICAL FIELD

The present disclosure relates to a model generation apparatus, a model generation method, and a program.

### BACKGROUND ART

Robots are introduced in various situations such as a manufacturing site, and before introduction of a robot, the motion of the robot is checked by simulation. When the motion of a robot is simulated, the design information of the robot is required, but in a case where the data amount of the design information such as CAD (Computer Aided Design) is enormous, there arises a problem that the processing speed of the simulation decreases. Therefore, it is required to reduce the data amount of the design information.

Here, Patent Literature 1 describes a technique of classifying a target three-dimensional object as a known shape from point cloud data composed of three-dimensional coordinates of the three-dimensional object. To be specific, in Patent Literature 1, the center of gravity of the point cloud data of the three-dimensional object is obtained and a principal component analysis with the center of gravity as the origin is performed, and furthermore, the Fourier coefficient is obtained from the coordinates, and the target three-dimensional object is classified as one known shape from these values.

### CITATION LIST

### Patent Literature

PTL 1: JP 2002-099556 A

### SUMMARY OF INVENTION

### Technical Problem

However, in the abovementioned technique described in Patent Literature 1, a three-dimensional object is merely classified as one known shape, so that there is a fear that the difference in shape from the object is large. Therefore, even if the technique of Patent Literature 1 is used in order to reduce the data amount of the design information as described above, the precision of the design information may decrease. As a result, the precision of simulation of a designed object decreases, and there arises a problem that the efficiency of the simulation cannot be improved.

Accordingly, an object of the present disclosure is to solve the abovementioned problem that the efficiency of simulation of a designed object cannot be promoted.

### Solution to Problem

A model generation apparatus as an aspect of the present disclosure includes: an acquiring means that acquires first design information of a designed object; a first generating means that generates occupancy information representing presence or absence of occupancy of the designed object in each position in a three-dimensional space, according to the first design information; and a second generating means that generates a model shape of the designed object composed of a combination of a plurality of default structures, according to the occupancy information.

Further, a model generation method as an aspect of the present disclosure includes: acquiring first design information of a designed object; generating occupancy information representing presence or absence of occupancy of the designed object in each position in a three-dimensional space, according to the first design information; and generating a model shape of the designed object composed of a combination of a plurality of default structures, according to the occupancy information.

Further, a program as an aspect of the present disclosure includes instructions for causing a computer to execute processes to: acquire first design information of a designed object; generate occupancy information representing presence or absence of occupancy of the designed object in each position in a three-dimensional space, according to the first design information; and generate a model shape of the designed object composed of a combination of a plurality of default structures, according to the occupancy information.

### Advantageous Effects of Invention

With the configurations as described above, the present disclosure enables the efficiency of simulation of a design object to be promoted.

### BRIEF DESCRIPTION OF DRAWINGS

FIG. 1 is a block diagram showing a configuration of a model generation apparatus in a first example embodiment of the present disclosure.

FIG. 2 is a diagram showing a state of processing by the model generation apparatus disclosed in FIG. 1.

FIG. 3 is a diagram showing a state of processing by the model generation apparatus disclosed in FIG. 1.

FIG. 4 is a diagram showing a state of processing by the model generation apparatus disclosed in FIG. 1.

FIG. 5 is a diagram showing a state of processing by the model generation apparatus disclosed in FIG. 1.

FIG. 6 is a flowchart showing operation of the model generation apparatus disclosed in FIG. 1.

FIG. 7 is a block diagram showing a hardware configuration of a model generation apparatus in a second example embodiment of the present disclosure.

FIG. 8 is a block diagram showing a configuration of the model generation apparatus in the second example embodiment of the present disclosure.

### EXAMPLE EMBODIMENT

### First Example Embodiment

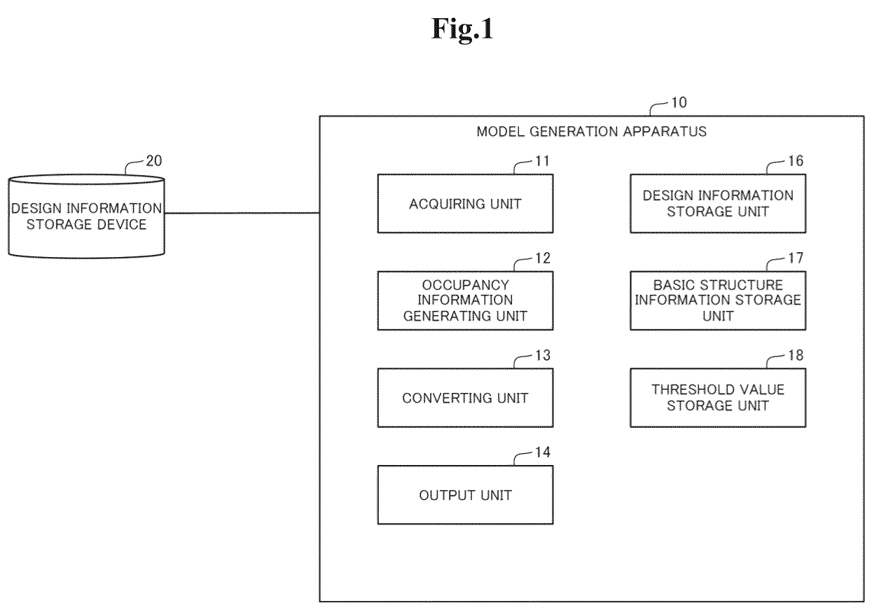

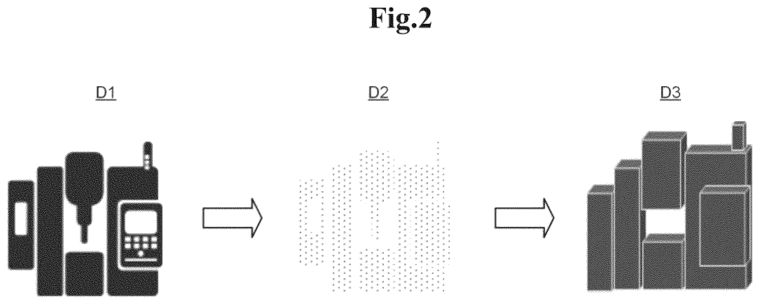

A first example embodiment of the present disclosure will be described with reference to FIGS. 1 to 6. FIG. 1 is a diagram for describing a configuration of a model generation apparatus, and FIGS. 2 to 6 are diagrams for describing processing operation of the model generation apparatus.

### Configuration

The model generation apparatus in this example embodiment is an apparatus for, in order to perform the motion check of a target system by simulation, generating a model of the system used for the simulation. In particular, the model generation apparatus generates a model from the design information such as CAD of a target system. At this time, the target system is a designed object designed by CAD or the like, for example, a robot introduced into a manufacturing site. In this case, simulation of a robot is to, using a model generated from the design information of the robot, check whether the robot performs a desired motion and whether an unintended collision occurs. However, a target system to generate a model is not limited to being a robot, and may be any system.

The model generation apparatus 10 is configured with one or a plurality of information processing apparatuses each including an arithmetic logic unit and a memory unit. Then, the model generation apparatus 10 includes an acquiring unit 11, an occupancy information generating unit 12, a converting unit 13, and an output unit 14, as shown in FIG. 1. The respective functions of the acquiring unit 11, the occupancy information generating unit 12, the converting unit 13, and the output unit 14 can be enabled by execution of a program for enabling the respective functions stored in the memory unit by the arithmetic logic unit. The model generation apparatus 10 also includes a design information storage unit 16, a basic structure information storage unit 17, and a threshold value storage unit 18. The design information storage unit 16, the basic structure information storage unit 17, and the threshold value storage unit 18 are configured with the memory unit. Furthermore, a design information storage device 20 is connected to the model generation apparatus 10. The respective components will be described in detail below.

First, the design information storage device 20 stores design information such as CAD data of a robot that is a designed object. The design information includes shape information and motion information of a robot in the three-dimensional space. As an example, the shape information is information representing the shape in the three-dimensional space of each component of the robot, and the motion information is information representing the motion trajectory and the movable range in the three-dimensional space of each component of the robot. However, the design information is not limited to the information described above.

The acquiring unit 11 (acquiring means) acquires design information (first design information) such as CAD data of a robot that is a designed object from the design information storage device 20 described above, and stores it into the design information storage unit 16. At this time, the design information to acquire includes the shape information and the motion information of the robot in the three-dimensional space as described above. For example, the acquiring unit 11 acquires design information of a robot including various components as denoted by reference sign D1 of FIG. 2.

The occupancy information generating unit 12 (first generating means) generates occupancy information representing the presence or absence of the component of the robot in each position in the three-dimensional space, in accordance with the acquired and stored design information of the robot. For example, the occupancy information generating unit 12 generates occupancy information as point cloud data in which a point is assigned to each position where the robot exists in the three-dimensional space. In this manner, the occupancy information generating unit 12 generates occupancy information including point cloud data as denoted by reference sign D2 with respect to the design information of the robot as denoted by reference sign D1 in FIG. 2.

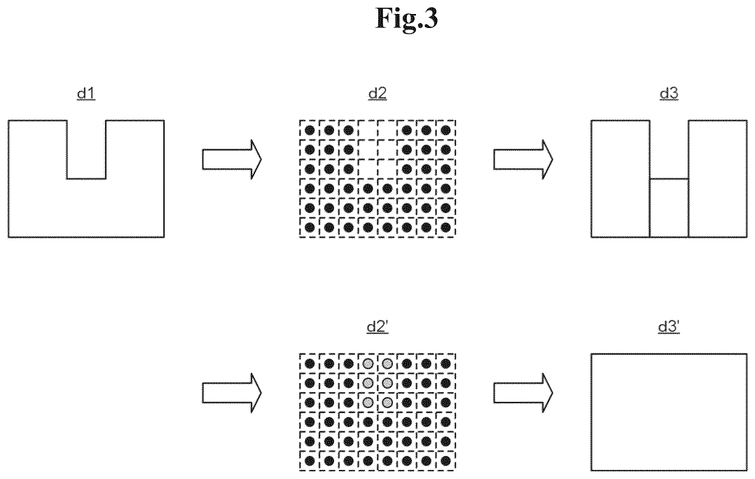

The details of a process of generating the occupancy information by the occupancy information generating unit 12 will be described with reference to FIG. 3. The occupancy information generating unit 12 first divides the three-dimensional space by into unit spaces with a predetermined density. Then, the occupancy information generating unit 12 assigns information representing whether the component of the robot is present in the position of each unit space obtained by division. For example, the occupancy information generating unit 12 divides the three-dimensional space in which the design information of the robot as denoted by reference sign dl of FIG. 3 is present into a plurality of unit spaces with a predetermined density as indicated by dotted line rectangles of reference sign d2. As an example, the occupancy information generating unit divides it into unit spaces composed of cubes with sides of 3 cm or 5 cm. Then, in a case where the component of the robot is present in the position of each unit space, the occupancy information generating unit 12 assigns a point representing that the unit space is occupied to the unit space. In this manner, the occupancy information generating unit 12 generates occupancy information composed of point cloud data as denoted by reference sign d2 with respect to the design information of the robot as denoted by reference sign dl in FIG. 3. FIG. 3 shows part of the structure of the robot.

The converting unit 13 (second generating means) generates a model shape of the robot composed of a combination of a plurality of basic structures (default structures) in accordance with the abovementioned occupancy information. To be specific, the converting unit 13 applies a basic structure containing unit spaces with points indicating the occupancy position of the robot component being assigned, to the occupancy information composed of point cloud data, thereby converting the occupancy information into a model shape composed of a plurality of basic structures. Consequently, the converting unit 13 converts the occupancy information composed of point cloud data as denoted by reference sign D2 of FIG. 2 into a model shape composed of a combination of a plurality of cuboids as denoted by reference sign D3.

The abovementioned basic structure is a default structure set in advance, such as a cuboid, a column, a cone, and a sphere. The shape of the basic structure is stored in advance in the basic structure information storage unit 17. Then, for the basic structure applied as the model shape, the size (length, height, radius, etc.), position (reference point position), and attitude (angle) are set in accordance with the dimension and orientation of the point cloud data contained thereby.

Here, the details of the conversion process by the converting unit 13 will be described with reference to FIG. 3. With respect to the occupancy information that is point cloud data as denoted by reference sign d2 of FIG. 3, the converting unit 13 applies the shape of a basic structure such as a cuboid to a collective region of unit spaces with points being assigned. At this time, the converting unit applies basic structures without excess or deficiency to the points of the point cloud data. For example, the converting unit applies large cuboids to the left and right sides and a small cuboid to the center of the point cloud data as denoted by reference sign d3 in FIG. 3. In this manner, the converting unit 13 converts the occupancy information composed of point cloud data as denoted by reference sign d2 of FIG. 3 into the model shape composed of a combination of a plurality of cuboids as denoted by reference sign d3.

The converting unit 13 also has a function of generating a model shape by modifying the occupancy information that is point cloud data, in accordance with the shape information and the motion information included in the design information of the robot. To be specific, the converting unit 13 determines whether a unit space that is not occupied by the structure of the robot on the point cloud data is a space where a predetermined part of the robot cannot move in accordance with the shape information and the motion information. Then, the converting unit 13 treats the non-occupied space where a part of the robot cannot move, as an occupied space. That is to say, the converting unit 13 assigns, to such a non-occupied unit space, a point representing that the unit space is occupied, and modify the occupancy information. For example, in a case where the shape of the collective region of non-occupied spaces is smaller than the shape of the minimum component of the robot, the converting unit 13 treats the occupied space as an occupied space. Moreover, in a case where it is not set that another part of the robot moves from the motion information in the position of the collective region of non-occupied spaces, the converting unit 13 treats the non-occupied space as an occupied space. Then, the converting unit 13 generates the model shape of the robot composed of a combination of a plurality of basic structures in the same manner as described above, from the occupancy information modified as described above.

Here, the details of the abovementioned occupancy information modification process by the converting unit 13 will be described with reference to FIG. 3. With respect to the occupancy information that is point cloud data as denoted by reference sign d2 of FIG. 3, in a case where the collective region of non-occupied unit spaces with no points being assigned is a region where another part cannot move, the converting unit 13 assigns a point (gray point) representing occupancy to each unit space of the region as denoted by reference sign d2′ of FIG. 3 and treats it as an occupied space. Then, the converting unit 13 applies a basic structure to the modified occupancy information denoted by reference sign d2′ of FIG. 3, thereby converting into a model shape composed of one cuboid as denoted by reference sign d3′ of FIG. 3. FIG. 3 shows part of the structure of the robot.

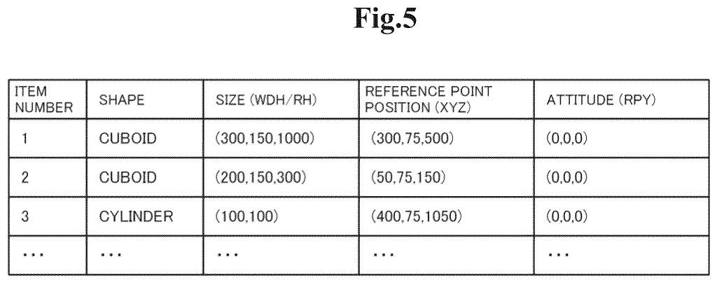

The output unit 14 generates and outputs model data representing the model shape obtained by conversion by the converting unit 13. To be specific, the output unit 14 acquires data identifying the shape in the three-dimensional space of each basic structure included in the model shape, for example, the type of shape (cuboid, cylinder, etc.), size (rectangle: W (width) D (depth) H (height), cylinder: R (radius) H (height)), reference point position (XYZ), and attitude (RPY (roll angle, pitch angle, yaw angle)) as shown in FIG. 5, and generates and outputs as model data. The attitude shown in FIG. 5 may not necessarily be included in the model data. In this case, the attitude of each basic structure is regarded as in an orientation set in advance.

Moreover, the output unit 14 may examine whether the generated model data satisfies a preset condition. For example, the output unit examines whether the data size of the model data is less than a data size threshold value stored in the threshold value storage unit 18, and whether the number of basic structures configuring the model data is less than a threshold value of the number of structures stored in the threshold value storage unit 18. Here, the data size threshold value and the structure threshold value are the upper limits of the data size and the number of basic structures that can be expected to suppress the load of the simulation device and suppress the decrease in the processing speed when simulation is performed using the model data, and are set in advance by experience, calculation formula, simulations and so forth and stored in the threshold value storage unit 18. Then, in a case where at least one of the data size and the number of basic structures of the model data is equal to or more than the threshold value, the output unit 14 notifies it to the occupancy information generating unit 12 and the converting unit 13, and performs regeneration of the model shape.

Here, the functions of the occupancy information generating unit 12 and the converting unit 13 when performing regeneration of the model shape will be described.

Upon receiving notification of regeneration of the model shape, the occupancy information generating unit 12 changes the density of unit spaces for dividing the three-dimensional space, that is, changes the dimension of the unit space, and divides the three-dimensional space into unit spaces again. At this time, as described above, regeneration of the model shape is performed because the data size of the model data representing the model shape previously generated is large or the number of basic structures is large, so that the data size and the number of basic structures are decreased. Therefore, the occupancy information generating unit 12 performs the change to decrease the density, which is the degree of congestion of unit spaces. That is to say, the occupancy information generating unit 12 greatly changes the dimension of the unit space, and divides the three-dimensional space into unit spaces. As an example, the occupancy information generating unit changes the division into unit spaces composed of cubes with sides of 5 cm to the division into unit spaces composed of cubes with sides of 10 cm.

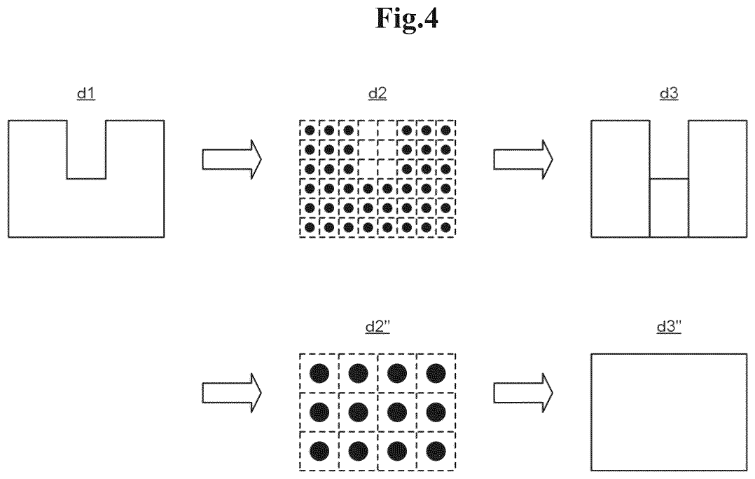

Here, with reference to FIG. 4, a process of changing the density of unit spaces above will be described. Reference sign d2 in FIG. 4 denotes a state before change of the density of unit spaces, and reference sign d2″ denotes a state after change of the density of unit spaces. As shown in this diagram, the occupancy information generating unit 12 greatly changes the dimension of the unit space, and divides the three-dimensional space into unit spaces. Then, the occupancy information generating unit 12 checks the presence or absence of occupancy by the component of the robot for each of the unit spaces obtained by largely changing the dimension and dividing, and in a case where the component of the robot exists in the position of each unit space, assigns a point representing that the unit space is occupied to the unit space. In this manner, the occupancy information generating unit 12 generates occupancy information composed of point cloud data after changing the density of unit spaces as denoted by reference sign d2″ with respect to the design information of the robot as denoted by reference sign dl in FIG. 3.

The occupancy information generating unit 12 may aggregate unit spaces from point cloud data before change of the density as denoted by reference sign d2 in FIG. 4, and generate occupancy information composed of point cloud data after change of the density as denoted by reference sign d2″. As an example, the occupancy information generating unit 12 may aggregate four unit spaces adjacent to each other denoted by reference sign d2 in FIG. 4 into one unit space, set the presence or absence of occupancy of the unit spaces after the aggregation from the statistical value such as the average value of the presence or absence of occupancy of the unit spaces before the aggregation, and generate modified point cloud data as shown by reference sign d2″ in FIG. 4.

Then, the converting unit 13 converts the modified occupancy information into a model shape composed of a combination of a plurality of basic structures in the same manner as described above, and generates model data. For example, with respect to part of the structure of the robot shown in Fig, the occupancy information before the modification denoted by reference sign d2 is converted into three basic structures denoted by reference sign d3, and the occupancy information after the modification denoted by reference sign d2″ is converted into one basic structure denoted by reference sign d3″. This achieves reduction of the data amount of the model data and the number of basic structures.

The regeneration of the model shape may be performed in such a manner that the data size of the model data and the number of basic structures configuring the model data get close to the respective threshold values stored in the threshold value storage unit 18 in a case where the data size and the number of basic structures are less than the respective threshold values. In this case, the occupancy information generating unit 12 described above performs the change to increase the density that is the degree of congestion of unit spaces, that is, make the dimension of the unit space smaller, and divides the three-dimensional space into unit spaces. However, even in this case, it is maintained that the data size of the model data and the number of basic structures configuring the model data are less than the respective threshold values.

Here, in order to achieve decrease of the data amount of the model data and the number of basic structures, the occupancy information generating unit 12 may specify an operation range of the components of the robot based on the motion information included in the design information of the robot, and generate the occupancy information described above only for the component of the robot located within the operation range. In this case, the converting unit 13 may convert the abovementioned occupancy information into a model shape and generate model data only for the component of the robot located in the operation range. In this case, the other components of the robot may not be included in the model data.

### Operation

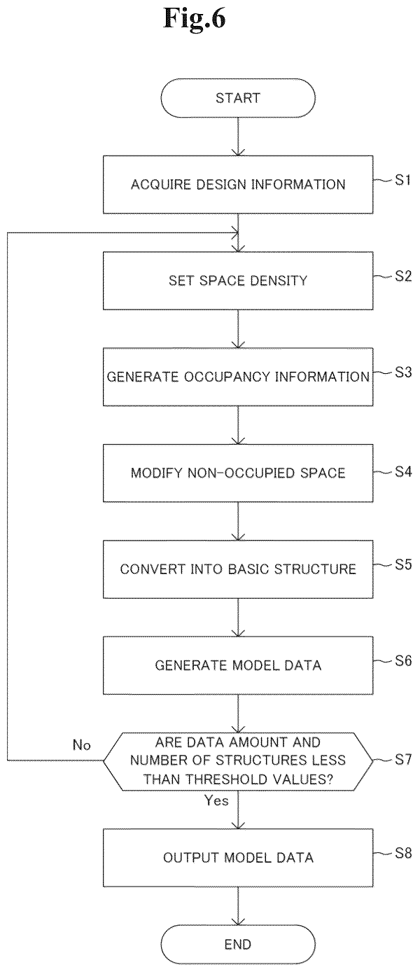

Next, the operation of the abovementioned model generation apparatus 10 will be described mainly with reference to a flowchart of FIG. 6.

First, the model generation apparatus 10 acquires design information such as CAD data of a robot that is a designed object, from the design information storage device 20 (step S1), and stores it into the design information storage unit 16. At this time, the acquired design information includes shape information and motion information of the robot in the three-dimensional space as described above. For example, the model generation apparatus 10 acquires the design information of the robot as denoted by reference sign D1 in FIG. 2.

Subsequently, the model generation apparatus 10 sets the density of unit spaces for dividing the three-dimensional space (step S2), and generates occupancy information representing the presence or absence of occupancy by a component of the robot in each of the positions of the unit spaces of the three-dimensional space based on the design information of the robot (step S3). For example, the model generation apparatus 10 divides the three-dimensional space into unit spaces at a density set as an initial value, and generates the occupancy information as point cloud data in which a point is assigned to each of the unit spaces occupied by the component of the robot. For example, the model generation apparatus 10 generates occupancy information composed of point cloud data as denoted by reference sign D2 with respect to the design information of the robot as denoted by reference sign D1 in FIG. 2.

Subsequently, the model generation apparatus 10 performs a process of modifying a non-occupied space on the occupancy information (step S4). To be specific, in a case where a collective region of non-occupied unit spaces to which no point is assigned in the generated point cloud data is a region where another part cannot move, the model generation apparatus 10 assigns a point representing occupancy to each of the unit spaces of the region and treats it as an occupied space. The model generation apparatus 10 may not necessarily execute the process of modifying the non-occupied space in step S4.

Subsequently, the model generation apparatus 10 converts the occupancy information composed of the point cloud data into a model shape of the robot composed of a combination of a plurality of basic structures (step S5). For example, the model generation apparatus 10 converts the occupancy information composed of point cloud data as denoted by reference sign D2 in FIG. 2 into a model shape composed of a combination of a plurality of cuboids as denoted by reference sign D3.

Subsequently, the model generation apparatus 10 generates model data representing the model shape obtained by conversion (step S6). To be specific, the model generation apparatus 10 acquires data identifying the shape in the three-dimensional space of each basic structure included in the model shape, such as the data as shown in FIG. 5, and generates it as model data.

At this time, the model generation apparatus 10 checks whether the generated model data satisfies a condition set in advance. For example, the model generation apparatus 10 checks whether the data size of the model data is less than a data size threshold value stored in the threshold value storage unit 18, and whether the number of basic structures configuring the model data is less than a threshold value of the number of structures stored in the threshold value storage unit 18 (step S7). Then, in a case where at least one of the data size of the model data and the number of basic structures is equal to or more than the threshold value (No in step S7), the model generation apparatus 10 performs regeneration of the model shape (return to step S2).

In the case of performing the regeneration of the model shape, the model generation apparatus 10 changes the density of unit spaces for dividing the three-dimensional space (step S2), and divides the three-dimensional space into unit spaces again and thereby generates occupancy information (step S3). For example, in order to decrease the data size of the model data and the number of basic structures, the model generation apparatus 10 performs the change to decrease the density that is the degree of congestion of unit spaces, that is, greatly change the dimension of the unit space, and divides the three-dimensional space into unit spaces. Then, the model generation apparatus 10 generates the occupancy information again with the changed unit spaces.

After that, the model generation apparatus 10 modifies a non-occupied space of the occupancy information in the same manner as described above (step S4), generates a model shape in which the occupancy information is converted into a combination of a plurality of basic structures (step S5), and generates model data (step S6). Then, the abovementioned process is repeated until the data size of the model data and the number of basic structures become less than the threshold values (step S7), and when they become less than the threshold values (Yes in step S7), the model data is output (step S8).

As described above, in this example embodiment, a model shape composed of a combination of a plurality of basic structures is generated from design information such as CAD data of a robot. Therefore, model data with reduced data size from design information can be used for simulation, and it is possible to inhibit decrease in simulation precision and processing speed and improve simulation efficiency.

Further, in this example embodiment, a non-occupied space that has a low influence on the robot simulation precision can be treated as an occupied space, and the number of basic structures to be combined can be decreased. As a result, it is possible to further improve simulation efficiency.

Further, in this example embodiment, a model shape composed of basic structures is formed at a space density such that the desired precision and speed of simulation can be obtained. Therefore, the number of basic structures to be combined can be reduced, and simulation efficiency can be further improved.

### Second Example Embodiment

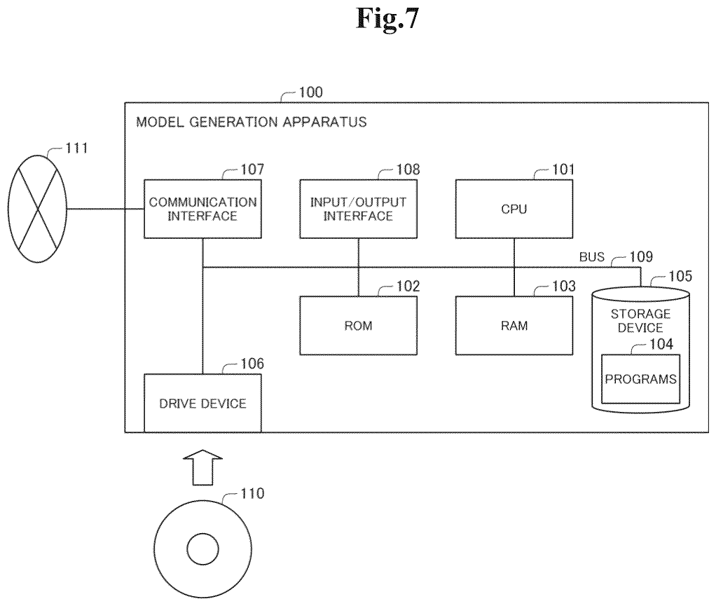

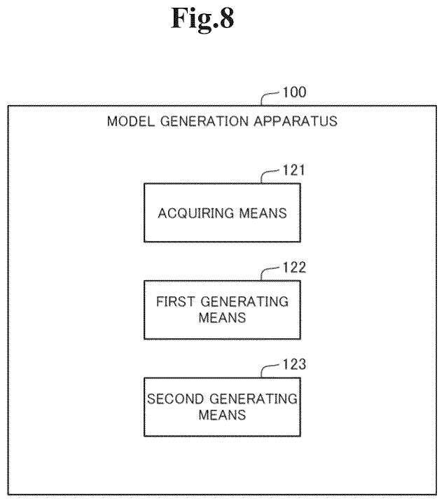

Next, a second example embodiment of the present disclosure will be described with reference to FIGS. 7 to 8. FIGS. 7 to 8 are block diagrams showing a configuration of a model generation apparatus in the second example embodiment. This example embodiment shows the overview of the configuration of the model generation apparatus described in the above example embodiment.

First, a hardware configuration of a model generation apparatus 100 in this example embodiment will be described with reference to FIG. 7. The model generation apparatus 100 is configured with a general information processing apparatus and, as an example, has the following hardware configuration including:
a CPU (Central Processing Unit) 101 (arithmetic logic unit);
a ROM (Read Only Memory) 102 (memory unit);
a RAM (Random Access Memory) 103 (memory unit);
programs 104 loaded into the RAM 103;
a storage device 105 storing the programs 104;
a drive device 106 that performs reading from and writing into a storage medium 110 external to the information processing apparatus;
a communication interface 107 connected to a communication network 111 external to the information processing apparatus;
an input/output interface 108 that performs input/output of data; and
a bus 109 connecting the components.

FIG. 7 shows an example of the hardware configuration of the information processing apparatus serving as the model generation apparatus 100, and the hardware configuration of the information processing apparatus is not limited to the abovementioned case. For example, the information processing apparatus may be configured with part of the abovementioned configuration, such as not having the drive device 106. Moreover, the information processing apparatus may use a GPU (Graphic Processing Unit), a DSP (Digital Signal Processor), an MPU (Micro Processing Unit), an FPU (Floating point number Processing Unit), a PPU (Physics Processing Unit), a TPU (Tensor Processing Unit), a quantum processor, a microcontroller, or a combination of these, instead of the abovementioned CPU.

Then, the model generation apparatus 100 can construct and include an acquiring means 121, a first generating means 122 and a second generating means 123 shown in FIG. 8 by acquisition and execution of the programs 104 by the CPU 101. The programs 104 are, for example, stored in advance in the storage device 105 or the ROM 102, and are loaded into the RAM 103 and executed by the CPU 101 as necessary. In addition, the programs 104 may be provided to the CPU 101 via the communication network 111, or the programs may be stored in advance in the storage medium 110 and read out by the drive device 106 and provided to the CPU 101. However, the acquiring means 121, the first generating means 122 and the second generating means 123 described above may be constructed using dedicated electronic circuit for realizing such means.

Then, the acquiring means 121 acquires first design information of a designed object, and the first generating means 122 generates occupancy information representing the presence or absence of occupancy of the designed object in each position in a three-dimensional space, based on the first design information. For example, the first generating means 122 generates, as occupancy information, point cloud data configured by assigning a point representing that a designed object is occupied to each position of the three-dimensional space.

Then, the second generating means 123 generates a model shape of the designed object composed of a combination of a plurality of default structures based on the occupancy information. At this time, the second generating means 123 can achieve reduction of the number of structures to be combined by treating even a non-occupancy position based on the shape of the designed object, as an occupancy position.

As described above, according to the model generation apparatus of the present disclosure, a model shape composed of a combination of a plurality of structures is generated from design information of a designed object. Therefore, model data with reduced data size from design information can be used for simulation, and it is possible to inhibit decrease in simulation precision and processing speed, and improve simulation efficiency.

The abovementioned program can be stored using various types of non-transitory computer-readable mediums and provided to a computer. The non-transitory computer-readable mediums include various types of tangible storage mediums.

Examples of the non-transitory computer-readable medium include a magnetic recording medium (e.g., flexible disk, magnetic tape, hard disk drive), a magneto-optical recording medium (e.g., magneto-optical disk), a CD-ROM (Read Only Memory), CD-R, CD-R/W, and a semiconductor memory (e.g., mask ROM, programmable ROM, erasable PROM, flash ROM, random access memory (RAM)). In addition, the program may be provided to the computer by various types of temporary computer-readable mediums. Examples of the temporary computer-readable medium include electrical signals, optical signals, and electromagnetic waves. The temporary computer-readable medium may provide the program to the computer via a wired communication channel such as an electric wire and an optical fiber, or via a wireless communication channel.

Although the present disclosure has been described above with reference to the above example embodiments, the present disclosure is not limited to the example embodiments described above. The configuration and details of the present disclosure can be changed in a variety of ways that those skilled in the art can understand within the scope of the present disclosure. In addition, at least one or more of the functions of the acquiring means 121, the first generating means 122, and the second generating means 123 may be performed by an information processing apparatus installed and connected anywhere on the network, that is, may be performed by so-called cloud computing.

### SUPPLEMENTARY NOTES

The whole or part of the example embodiments disclosed above can be described as the following supplementary notes. Hereinafter, the overview of the configurations of a model generation apparatus, a model generation method and a program in the present disclosure will be described. However, the present disclosure is not limited to the following configurations.

### Supplementary Note 1

A model generation apparatus comprising:
an acquiring means that acquires first design information of a designed object;
a first generating means that generates occupancy information representing presence or absence of occupancy of the designed object in each position in a three-dimensional space, according to the first design information; and
a second generating means that generates a model shape of the designed object composed of a combination of a plurality of default structures, according to the occupancy information.

### Supplementary Note 2

The model generation apparatus according to supplementary note 1, wherein
the second generating means generates the model shape composed of the combination of the structures containing an occupancy position of the designed object in the three-dimensional space, according to the occupancy information.

### Supplementary Note 3

The model generation apparatus according to supplementary note 2, wherein
the second generating means treats, in accordance with a shape of a non-occupancy position of the design object in the three-dimensional space based on the occupancy information, the non-occupancy position as the occupancy position.

### Supplementary Note 4

The model generation apparatus according to supplementary note 2, wherein:
the acquiring means acquires motion information of the designed object; and
the second generating means treats a non-occupancy position of the designed object in the three-dimensional space as the occupancy position, according to the occupancy information and the motion information.

### Supplementary Note 5

The model generation apparatus according to supplementary note 4, wherein
the second generating means treats the non-occupancy position of the designed object where a predetermined portion of the designed object cannot move in the three-dimensional space, as the occupancy position, according to the occupancy information and the motion information.

### Supplementary Note 6

The model generation apparatus according to supplementary note 1, wherein:
the acquiring means acquires motion information of the designed object; and
the first generating means generates the occupancy information only for a motion range of the designed object in the three-dimensional space, according to the motion information.

### Supplementary Note 7

The model generation apparatus according to supplementary note 1, wherein
the first generating means sets density of each position in the three-dimensional space in such a manner that the model shape to be generated satisfies a preset condition, and generates the occupancy information.

### Supplementary Note 8

The model generation apparatus according to supplementary note 7, wherein
the first generating means sets the density of each position in the three-dimensional space in such a manner that a data size of the model shape to be generated becomes less than a preset threshold value, and generates the occupancy information.

### Supplementary Note 9

The model generation apparatus according to supplementary note 7, wherein
the first generating means sets the density of each position in the three-dimensional space in such a manner that a number of the structures configuring the model shape to be generated becomes less than a preset threshold value, and generates the occupancy information.

### Supplementary Note 10

A model generation method comprising:
acquiring first design information of a designed object;
generating occupancy information representing presence or absence of occupancy of the designed object in each position in a three-dimensional space, according to the first design information; and
generating a model shape of the designed object composed of a combination of a plurality of default structures, according to the occupancy information.

### Supplementary Note 11

The model generation method according to supplementary note 10, comprising
generating the model shape composed of the combination of the structures containing an occupancy position of the designed object in the three-dimensional space, according to the occupancy information.

### Supplementary Note 12

The model generation method according to supplementary note 11, comprising
treating, in accordance with a shape of a non-occupancy position of the design object in the three-dimensional space based on the occupancy information, the non-occupancy position as the occupancy position.

### Supplementary Note 13

The model generation method according to supplementary note 11, comprising:
acquiring motion information of the designed object; and
treating a non-occupancy position of the designed object in the three-dimensional space as the occupancy position, according to the occupancy information and the motion information.

### Supplementary Note 14

The model generation method according to supplementary note 10, comprising
setting density of each position in the three-dimensional space in such a manner that the model shape to be generated satisfies a preset condition, and generating the occupancy information.

### Supplementary Note 15

A non-transitory computer-readable storage medium storing a program, the program comprising instructions for causing a computer to execute processes to:
acquire first design information of a designed object;
generate occupancy information representing presence or absence of occupancy of the designed object in each position in a three-dimensional space, according to the first design information; and
generate a model shape of the designed object composed of a combination of a plurality of default structures, according to the occupancy information.

### REFERENCE SIGNS LIST

10 model generation apparatus
11 acquiring unit
12 occupancy information generating unit
13 converting unit
14 output unit
16 design information storage unit
17 basic structure information storage unit
18 threshold value storage unit
20 design information storage device
100 model generation device
101 CPU
102 ROM
103 RAM
104 programs
105 storage device
106 drive device
107 communication interface
108 input/output interface
109 bus
110 storage medium
111 communication network
121 acquiring means
122 first generating means
123 second generating means

What is claimed is:

1. A model generation apparatus comprising:
at least one memory storing processing instructions; and
at least one processor configured to execute the processing instructions, wherein the at least one processor executes the processing instructions to:
acquire first design information of a designed object;
generate occupancy information representing presence or absence of occupancy of the designed object in each position in a three-dimensional space, according to the first design information; and
generate a model shape of the designed object composed of a combination of a plurality of default structures, according to the occupancy information.

2. The model generation apparatus according to claim 1, wherein the at least one processor executes the processing instructions to
generate the model shape composed of the combination of the structures containing an occupancy position of the designed object in the three-dimensional space, according to the occupancy information.

3. The model generation apparatus according to claim 2, wherein the at least one processor executes the processing instructions to
treat, in accordance with a shape of a non-occupancy position of the design object in the three-dimensional space based on the occupancy information, the non-occupancy position as the occupancy position.

4. The model generation apparatus according to claim 2, wherein the at least one processor executes the processing instructions to:
acquire motion information of the designed object; and
treat a non-occupancy position of the designed object in the three-dimensional space as the occupancy position, according to the occupancy information and the motion information.

5. The model generation apparatus according to claim 4, wherein the at least one processor executes the processing instructions to
treat the non-occupancy position of the designed object where a predetermined portion of the designed object cannot move in the three-dimensional space, as the occupancy position, according to the occupancy information and the motion information.

6. The model generation apparatus according to claim 1, wherein the at least one processor executes the processing instructions to:
acquire motion information of the designed object; and
generate the occupancy information only for a motion range of the designed object in the three-dimensional space, according to the motion information.

7. The model generation apparatus according to claim 1, wherein the at least one processor executes the processing instructions to
set density of each position in the three-dimensional space in such a manner that the model shape to be generated satisfies a preset condition, and generate the occupancy information.

8. The model generation apparatus according to claim 7, wherein the at least one processor executes the processing instructions to
set the density of each position in the three-dimensional space in such a manner that a data size of the model shape to be generated becomes less than a preset threshold value, and generate the occupancy information.

9. The model generation apparatus according to claim 7, wherein the at least one processor executes the processing instructions to
set the density of each position in the three-dimensional space in such a manner that a number of the structures configuring the model shape to be generated becomes less than a preset threshold value, and generate the occupancy information.

10. A model generation method comprising:
acquiring first design information of a designed object;
generating occupancy information representing presence or absence of occupancy of the designed object in each position in a three-dimensional space, according to the first design information; and
generating a model shape of the designed object composed of a combination of a plurality of default structures, according to the occupancy information.

11. The model generation method according to claim 10, comprising
generating the model shape composed of the combination of the structures containing an occupancy position of the designed object in the three-dimensional space, according to the occupancy information.

12. The model generation method according to claim 11, comprising
treating, in accordance with a shape of a non-occupancy position of the design object in the three-dimensional space based on the occupancy information, the non-occupancy position as the occupancy position.

13. The model generation method according to claim 11, comprising:
acquiring motion information of the designed object; and
treating a non-occupancy position of the designed object in the three-dimensional space as the occupancy position, according to the occupancy information and the motion information.

14. The model generation method according to claim 10, comprising
setting density of each position in the three-dimensional space in such a manner that the model shape to be generated satisfies a preset condition, and generating the occupancy information.

15. A non-transitory computer-readable storage medium storing a program, the program comprising instructions for causing a computer to execute processes to:
acquire first design information of a designed object;
generate occupancy information representing presence or absence of occupancy of the designed object in each position in a three-dimensional space, according to the first design information; and
generate a model shape of the designed object composed of a combination of a plurality of default structures, according to the occupancy information.
